(19) United States
(12) Patent Application Publication
(10) Pub. No.: US 2024/0053388 A1
(43) Pub. Date: Feb. 15, 2024

(54) METHOD AND DEVICE FOR CORRECTING SENSOR DATA

(71) Applicant: Siemens Aktiengesellschaft, München (DE)

(72) Inventors: Marco Brüll, Berlin (DE); Peter Kopaczewski, Berlin (DE); Thomas Driehorn, Teltow (DE); Jakob Hüttner, Hirschau (DE)

(21) Appl. No.: 18/448,303

(22) Filed: Aug. 11, 2023

(30) Foreign Application Priority Data
Aug. 11, 2022 (DE) 10 2022 208 345.8

(51) Int. Cl. G01R 19/25; G01R 19/165

(52) U.S. Cl. CPC G01R 19/2506; G01R 19/16533

(57) ABSTRACT

Values of a physical quantity acquired by a sensor unit are corrected with a correction value. A functional correlation) exists between the values of the physical quantity and the correction value. At least one value of the physical quantity acquired by the sensor unit is corrected by applying a correction value to it determined by way of the functional correlation. A new correction value is determined by way of the functional relationship on the basis of the at least one value of the physical quantity captured by the sensor unit. Finally, at least one value of the physical quantity acquired by a sensor unit is corrected by applying the new correction value to it.

### CROSS-REFERENCE TO RELATED APPLICATION

This application claims the priority, under 35 U.S.C. § 119, of German Patent Application DE 10 2022 208 345.8, filed Aug. 11, 2022; the prior application is herewith incorporated by reference in its entirety.

### FIELD AND BACKGROUND OF THE INVENTION

The invention relates to a method, a device, and a computer program product for correcting values of a physical quantity acquired by a sensor unit.

Circuit breakers are protection devices, which function in a similar way to a fuse. Circuit breakers monitor the current flowing through them by way of a conductor and interrupt the electric current or flow of energy to an energy sink or a load, which is referred to as tripping, when protection parameters, such as current limit values or current/time period limit values, that is to say when a current value is present for a certain time period, are exceeded. The set current limit values or current/time period limit values are corresponding reasons for tripping. The interruption is effected, for example, by contacts of the circuit breaker, which are opened.

Particularly for low-voltage circuits, installations or supply systems, there are various types of circuit breakers, depending on the level of the provided electric current in the electrical circuit. Within the meaning of the invention, low-voltage circuit breakers are understood to mean in particular switches as are used in low-voltage installations for currents, in particular rated currents or maximum currents, of from 63 to 6300 amperes. Molded case circuit breakers are especially used for currents from 63 to 1600 amperes, in particular for currents from 125 to 630 or 1200 amperes. Air circuit breakers are used, in particular, for currents from 200 or 630 to 6300 amperes, especially from 1200 to 6300 amperes.

Air circuit breakers are also identified by their acronym ACB and molded case circuit breakers are identified by their acronym MCCB for short.

The term “low voltage” is understood to mean voltages of up to 1000 or 1200 volts AC or 1500 volts DC, the root mean square (RMS) values of the voltage in particular being meant here. Low voltage is more specifically understood to mean, in particular, voltages that are greater than extra-low voltage, with values of 50 volts AC or 120 volts DC.

Within the meaning of the invention, circuit breakers are understood to mean, in particular, circuit breakers with an electronic trip unit, ETU for short, which serves as control unit.

In low-voltage circuit breakers, the level of the voltage is usually ascertained by way of voltage sensors. To determine the current levels, so-called Rogowski coils (Rogowski transducers) are usually used which have the advantages of potential isolation, a high current resistance, and a small size. Rogowski coils output a voltage proportional to the differential current. The level of the current may be ascertained by integrating this voltage. Due to the very large dynamic range of circuit breakers, a combination of a Rogowski transducer and an analog integrator is often used for current measurement. A solution with a digital integrator is also known from the commonly assigned German published patent application DE 102015216981 A1. Rogowski transducers in the form of so-called combi-transducers are also used, in which a second transducer, a so-called energy transformer (iron core transformer) is accommodated for supplying power to the ETU of a circuit breaker.

The arrangement of the Rogowski transducer and analog integrator by its nature has a non-linear transfer function (amplitude response) in relation to the signal it is used to measure (e.g., current). The non-linear transfer function results in an amplitude-dependent error in the measured signal.

Modern circuit breakers increasingly perform the tasks of so-called PMD devices (PMD: power measurement device), which are used for acquiring energy data. Above all, the accuracy of the measured values (e.g., current, voltage, energy, power, and phase angle) in accordance with the associated PMD standard is critical.

### SUMMARY OF THE INVENTION

It is therefore desirable to perform measured variable detection with high accuracy, in particular satisfying PMD standards. It is accordingly an object of the invention to provide a method and a device which overcomes a variety of the disadvantages associated with the prior art and which provides for accurate and efficient correction of sensor data.

With the above and other objects in view there is provided, in accordance with the invention, a method for correcting values of a physical quantity acquired by a sensor unit, the method comprising:
providing a functional correlation between the values of the physical quantity and correction values;
correcting at least one value of the physical quantity acquired by the sensor unit by applying to the at least one value a correction value determined by the functional correlation;
determining a new correction value by way of the functional correlation on a basis of the at least one value of the physical quantity acquired by the sensor unit; and
correcting at least one value of the physical quantity acquired by the sensor unit by applying the new correction value to the at least one value and outputting the corrected value of the physical quantity as a corrected sensor output.

In other words, according to the method according to the invention, a correction is applied to values of a physical quantity acquired by a sensor unit (e.g., current or voltage). This assumes a functional correlation between values of the physical quantity and correction values.

A “functional correlation” refers to a mapping that assigns correction values to the values of the physical quantity. This functional correlation can be determined, for example, by means of a multi-point calibration. For a plurality of known values (possibly mean values) of the physical quantity, the deviation from values acquired by the sensor unit is determined and an interpolation is performed between the plurality of values. The functional correlation can exist in a fully determined form (e.g., in tabular form) or be given at least partially as an assignment rule, on the basis of which the corresponding correction value for a value of the physical variable is calculated on demand (e.g., by interpolation).

According to the invention, at least one value of the physical quantity acquired by the sensor unit is corrected by applying a correction value to it that is determined by means of the functional correlation. Preferably, a first number of values of the physical quantity detected by the sensor unit is defined, which are then corrected by means of a correction value. This number corresponds, for example, to a number of values that are averaged (e.g., squared mean) in order to obtain a value for display via a monitor (display value).

Furthermore, a new correction value is determined by means of the functional correlation on the basis of the at least one value of the physical quantity captured by the sensor unit. Preferably, the value is determined on the basis of a second number of values of the physical quantity. More preferably, the second number corresponds to the first number, and the values of the physical quantity are those that were corrected with the previously used correction value immediately before the calculation of the new correction value. It may be provided that an averaging of the second number of physical quantity values acquired by the sensor unit is performed and the new correction value is determined by means of the functional correlation on the basis of the mean value obtained by the averaging.

Once the new correction value has been determined, it is used to correct at least one value of the physical quantity acquired by a sensor unit by applying a mathematical operation to it (e.g., multiplication). Preferably, a number of values of the physical quantity that corresponds to the first number mentioned above is corrected.

Preferably, new correction values are determined continuously, which replace the previously valid correction values, provided the operation is continuous. This ensures that the best possible correction of the acquired physical quantity values is always carried out. The invention can be used, for example, for a device comprising a circuit breaker having the sensor unit and a control unit (in particular ETU) for carrying out method steps. Continuous operation in the above sense would then be defined, for example, by switching the circuit breaker on and off.

An inventive idea is that values acquired by the sensor unit and corrected by means of a correction factor are themselves used again to determine a new correction factor. Another inventive idea is the continuous adjustment of correction factors. In principle, only one current correction factor must ever be present or stored. This means that the method according to the invention can be implemented in a very resource-saving manner.

The method according to the invention can also be provided in the form of a computer program product, e.g., for circuit breakers. The computer program product then consists, for example, of software that is transferred to the circuit breaker via a wireless interface or a cable interface, for example, as part of an update, and implemented there.

Other features which are considered as characteristic for the invention are set forth in the appended claims.

Although the invention is illustrated and described herein as being embodied in the accurate and efficient correction of sensor data, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 is a schematic view of elements of a circuit breaker;

FIG. 2 is a graph showing the error bandwidth in the current measurement with a conventional correction;

FIG. 3 is a similar graph showing the error bandwidth in the current measurement with a correction according to the invention;

FIG. 4 is a schematic procedure for performing a correction of measured values according to the invention; and

FIG. 5 is a flowchart for a procedure according to the invention for correcting measured values.

### DETAILED DESCRIPTION OF THE INVENTION

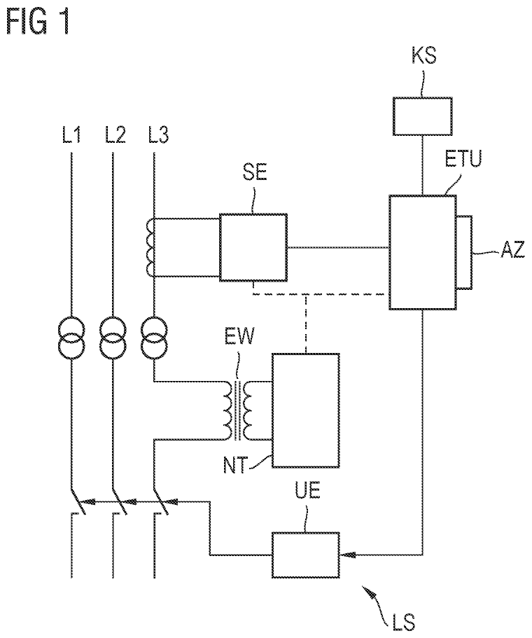

Referring now to the figures of the drawing in detail and first, in particular, to FIG. 1 thereof, there is shown a part of a circuit breaker LS, wherein different units of the switch are shown schematically. The circuit breaker is designed to disconnect electrical conductors L1, L2, L3 of an electrical circuit, for example a three-phase AC circuit, wherein the first conductor L1 forms the first phase, the second conductor L2 forms the second phase, and the third conductor L3 forms the third phase of the three-phase AC circuit. A neutral conductor and a protective conductor can also be provided.

In the example of FIG. 1, the third conductor L3 is connected to the energy converter EW in such a way that at least a portion of the current, that is to say a partial conductor current, or the entire current of the third conductor flows through the primary side of an energy converter EW. The energy converter EW is usually a transformer with a core. An energy converter EW may also be provided in each phase or in each conductor of the electrical circuit. The secondary side of the energy converter EW is connected to a power supply unit NT, which provides a power supply, for example in the form of a supply voltage, for a control unit ETU (Electronic Trip Unit). A sensor unit SE is provided, which is formed with at least one sensor element for determining the level of the electrical current, preferably a Rogowski coil. In a common design variant, the level of the electric current of each phase conductor or conductor of the electrical circuit is determined.

The sensor unit SE is connected to the control unit ETU and transmits the level of the electric current of at least one or more conductors of the electrical circuit to said control unit.

The transmitted current values are compared in the control unit ETU with current limit values or/and current/time period limit values, which form reasons for tripping. If said limit values are exceeded, interruption of the electrical circuit is prompted. This may be realized, for example, by virtue of the provision of an interruption unit UE, which is connected on one side to the control unit ETU and on the other side has contacts for interrupting the conductors L1, L2, L3 or further conductors of the electrical circuit. The interruption unit UE in this case receives an interruption signal for opening the contacts.

The ETU control unit is equipped with a display AZ, on which values of system-relevant variables can be displayed, e.g., current, voltage, energy, power, phase angle, etc. These are partly measured and partly calculated from measured values. A communication interface KS (e.g., ZigBee, WiFi or BLE radio interface or cable interface, e.g., for LAN cables), via which the acquired system-relevant values can be transmitted to a monitoring point, for example, for display or analysis. Configurations are also conceivable in which there is no display provided on the control unit ETU, but only by means of an external unit to which information is transmitted. The calculation of system-relevant values from measured values can be carried out both in the circuit breaker LS or by an external unit to which measured values have been transferred. It is therefore also possible that the circuit breaker either has no display AZ or has no communication interface KS. In the first case, a display would only be provided on the circuit breaker LS, while in the second case a display would be provided by an external unit, which is fed with data from the circuit breaker.

In the following, the invention is explained based on the acquisition of current values. The sensor unit SE then comprises a current sensor or is designed as a current sensor. Specifically, the current sensor can be formed with a Rogowski coil and an analog integrator. However, the invention is not limited to this specific measurement (current) or to this specific sensor design (Rogowski coil with integrator), but can be used for correction of any measured values acquired with suitable sensors.

The following assumes a mains frequency of 50 Hz and distinguishes between sampling frequency and display frequency or between sampled values and display values. For example, a current measurement is carried out with each half-wave, i.e., every 10 ms (sampled values). The display of values takes into account the physiological properties of the human eye. For example, one value (display value) is displayed every 200 ms. The display value is formed, for example, by the squared mean of the samples in a 200 ms interval. These values are often referred to as RMS (root mean square) values.

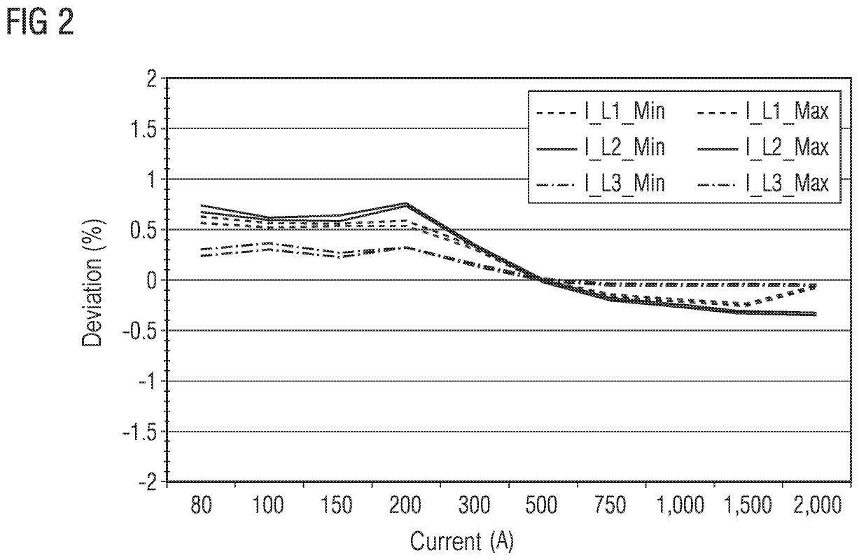

FIG. 2 shows an example of measurement series for a conventional correction using a calibration point. Measurement series of the current of three phases L1, L2 and L3 were acquired and the minimum and maximum values (I_L1_min, I_L1_max, I_L2_min, I_L2_max, I_L3_min and I_L3_max) of the measurement series were plotted as curves for each of the three phases. The abscissa shows RMS values of the current and the ordinate shows the deviation between the curves in percent.

For improved correction, a multi-point calibration can be performed. In this process, the correction factor is determined for multiple points (current values), i.e., for a known signal, the measured signal is corrected accordingly to compensate for the deviation from the known signal supplied. The correction values are then determined for the plurality of current values used in the multi-point calibration. Correction values for arbitrary current values can then be obtained by interpolation of the correction factors. Mathematically formulated, correction factors k(ij), j=1 . . . nP are obtained, where the index j ranges over the current values ij for which the correction factor k(ij) is determined in the course of the multi-point calibration for a known signal ij by comparison with the measurement signal, and nP corresponds to the number of points used for the multi-point calibration. The correction factor for any measured values can then be obtained by interpolation of the correction factors k(ij). For example, assume ij<I<ij+1. In a linear interpolation the correction factor is calculated as

k(i)=k(ij)+(k(ij+1)−k(ij))/(ij+1−ij)*(i−ij).

Interpolation methods other than a linear interpolation method (e.g., interpolation with cubic splines) can also be used.

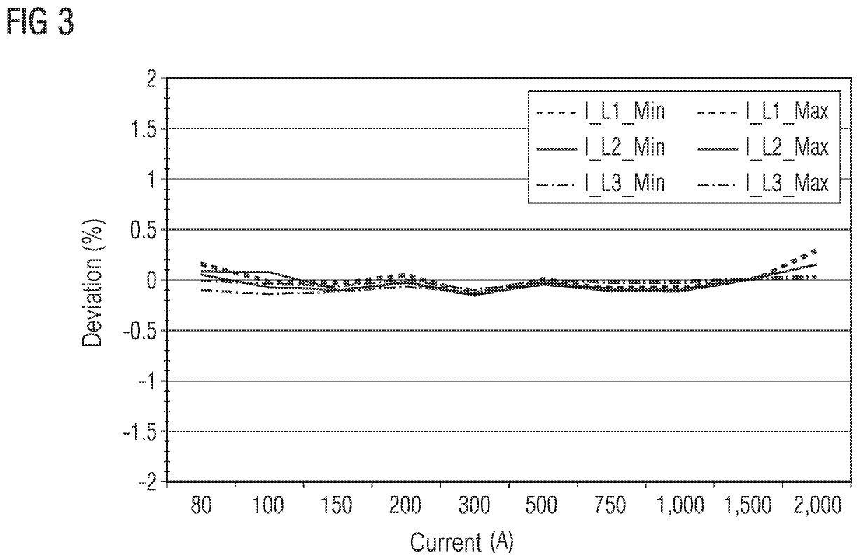

FIG. 3 shows the effect of improved correction on the measurement signals. The measurement series correspond to those of FIG. 2, wherein now a correction has been carried out by means of a multi-point calibration. The accuracy of the measured values (deviations in the measurement series) is approximately five times greater. In FIG. 2 it can be seen that the inaccuracy at small current values is increased, which corresponds to a higher non-linearity of the transfer function. Calibration points for the multipoint compensation are therefore set particularly in the range of the largest non-linearity of the transfer function of the measurement channel. This means that the compensation algorithm achieves a higher measurement accuracy of the measured values (as well as the dependent measured variables).

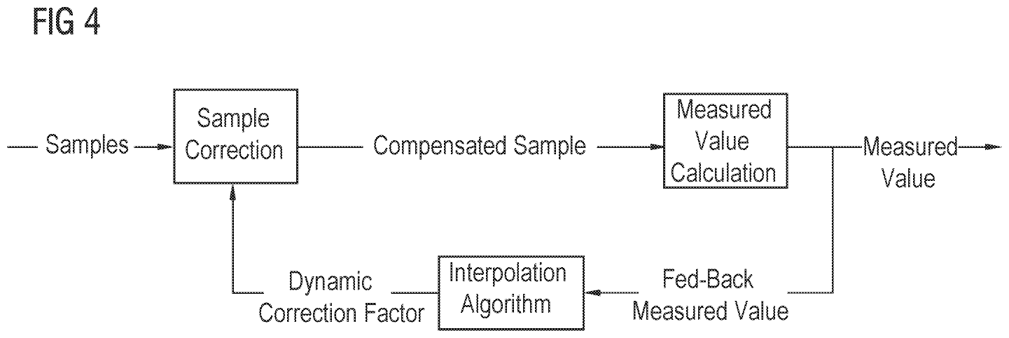

FIG. 4 shows the principle of the procedure in a method according to the invention for correcting measured values and adjusting the measured value correction. The sensor unit SE is used to acquire measured values or samples and transfer them to the control unit ETU. The processing of the samples by the control unit consists firstly of correcting the measured values with the current correction factor. Corrected measured values or compensated samples are obtained, which are used to calculate additional measured values (phase shift, power, etc.) and display values (averaging of measured values). Corrected measured values are fed back to update the correction factor. From these, using the interpolation algorithm (interpolated multi-point calibration), an updated correction factor is obtained (referred to in the figure as a “dynamic correction factor”), which replaces the previously used correction factor for the correction of measured values. This means that the correction factor is “dynamic” in the sense that it is continuously adjusted.

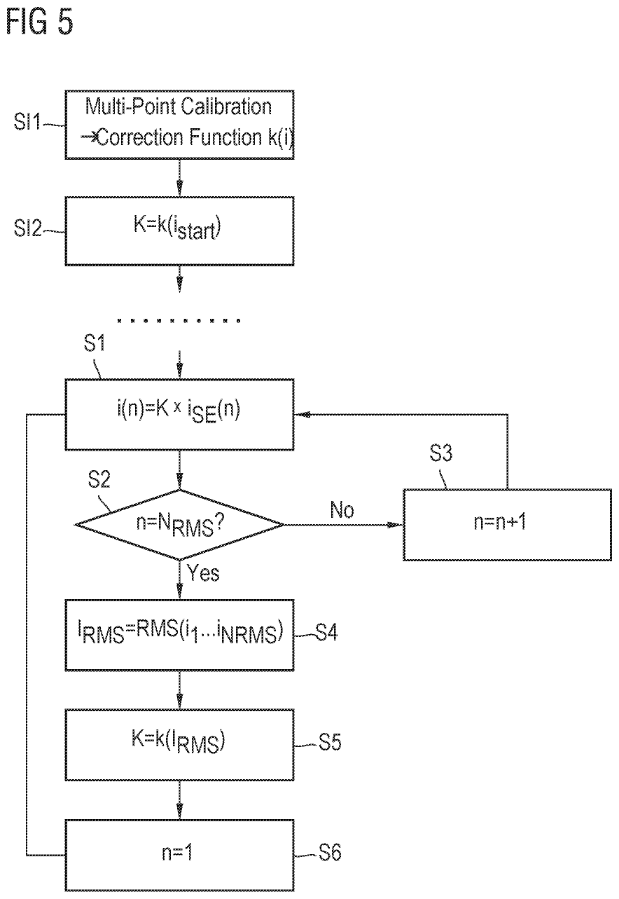

FIG. 5 shows an example of a concrete procedure according to FIG. 4. In a first initialization step SI1, the multipoint calibration takes place, whereby a correction function k(i) is defined. The calibration points can be interpolated at this point and the function values can be stored, for example, in the form of a table. Alternatively, interpolation (e.g., according to the above formula for k(i)) takes place only when the correction factor (step S5) is recalculated. In a second initialization step SI2, the correction factor is set to a starting value: K=k(istart). This starting value typically corresponds to the correction for a small current (once switched on) and can be set empirically at the factory. The following steps are then iterated continuously during operation (or at least during the recording of measured values) as a loop. The current measurement iSE(n), which is recorded by the sensor unit SE and delivered to the control unit ETU, is multiplied by the correction factor K to obtain a corrected value i(n), i.e., i(n)=K×iSE(n). Step S2 checks whether n is equal to a value NRMS, which corresponds to the number of samples averaged to form a display value. If n<NRMS, n is incremented (step S3) and the next measured value is corrected with the same correction factor K. If n is equal to NRMS, the mean value IRMS is calculated from the last NRMS samples (step S4: IRMS=RMS(i1 . . . iRMS), where the abbreviation RMS denotes the averaging). In the next step S5, an updated correction factor is calculated for the mean value IRMS using the function k(i) obtained by the multi-point calibration: K=k(IRMS). In fact, the mean value IRMS can also be displayed as a display value, e.g., by the display AZ. In a next step S6, the index n is reset to 1. The measured values acquired in the sequence are then corrected with the updated correction factor K.

The invention has been explained above based on only one example. Other embodiments or implementations will be obvious to the person skilled in the art and are therefore to be subsumed under the procedure according to the invention.

1. A method for correcting values of a physical quantity acquired by a sensor unit, the method comprising:
providing for a functional correlation between the values of the physical quantity and correction values;
correcting at least one value of the physical quantity acquired by the sensor unit by applying to the at least one value a correction value determined by the functional correlation;
determining a new correction value by way of the functional correlation on a basis of the at least one value of the physical quantity acquired by the sensor unit; and
correcting at least one value of the physical quantity acquired by the sensor unit by applying the new correction value to the at least one value and outputting the corrected value of the physical quantity as a corrected sensor output.

2. The method according to claim 1, which comprises correcting a plurality of values of the physical quantity acquired by the sensor unit with a given correction value before the new correction value is determined.

3. The method according to claim 2, which comprises determining the new correction value by way of the functional correlation on a basis of the values of the plurality of values of the physical quantity.

4. The method according to claim 2, wherein a number of the plurality of values is equal to a number of acquired values that are averaged to obtain display values.

5. The method according to claim 2, which comprises:
averaging the plurality of values of the physical quantity acquired by the sensor unit; and
determining the new correction value by way of the functional correlation on a basis of a mean value obtained by the averaging.

6. The method according to claim 1, which comprises determining the functional correlation) between the values of the physical quantity and the correction values by a multi-point calibration.

7. The method according to claim 6, which comprises:
for multiple known values of the physical quantity, determining a deviation from values acquired by the sensor unit; and
performing an interpolation between the multiple values.

8. The method according to claim 1, wherein the physical quantity is an electric current or a voltage.

9. A device which is configured for carrying out a method according to claim 1.

10. The device according to claim 9, comprising:
a circuit breaker having:
the sensor unit; and
a control unit that is configured to carry out the steps of the method according to claim 1.

11. A computer program product, comprising a non-transitory computer program that is configured to execute the steps of the method according to claim 1 when the computer program is executed on a processing unit.
